(19) United States
(12) Patent Application Publication
(10) Pub. No.: US 2025/0316301 A1
(43) Pub. Date: Oct. 9, 2025

(54) APPARATUSES AND METHODS FOR ACTIVATION COUNTER INITIALIZATION

(71) Applicant: MICRON TECHNOLOGY, INC., BOISE, ID (US)

(72) Inventors: Yang Lu, Boise, ID (US); Kang-Yong Kim, Boise, ID (US); Mark Hadrick, Boise, ID (US); Donald M. Morgan, Meridian, ID (US); Victor Wong, Boise, ID (US); Yoshiro Riho, Tokyo (JP); Aaron Zenner, Boise, ID (US)

(73) Assignee: MICRON TECHNOLOGY, INC., Boise, ID (US)

(21) Appl. No.: 19/086,994

(22) Filed: Mar. 21, 2025

Related U.S. Application Data
(60) Provisional application No. 63/574,047, filed on Apr. 3, 2024.

(51) Int. Cl. G11C 11/406; G11C 11/4072; G11C 11/408

(52) U.S. Cl. CPC G11C 11/40615; G11C 11/40622; G11C 11/4072; G11C 11/4087

(57) ABSTRACT

Embodiments of the disclosure are drawn to apparatuses, systems, and methods for activation counter initialization (ACI). A memory may be placed in an ACI mode. During the ACI mode, an ACI control circuit initializes the access count values of the memory array to an initialization value. For example, the ACI mode may work through the array on a row-by-row basis initializing the access count values along each of the rows. By controlling the initial state of the access count values, it is less likely to have a false aggressor alert because none of the access count values start at a randomly high number, simulating an aggressor even after a small number of accesses.

### CROSS-REFERENCE TO RELATED APPLICATIONS

This application claims the filing benefit of U.S. Provisional Application No. 63/574,047, filed Apr. 3, 2024. This application is incorporated by reference herein in its entirety and for all purposes.

### BACKGROUND

Information may be stored on individual memory cells of the memory as a physical signal (e.g., a charge on a capacitive element). The memory may be a volatile memory, and the physical signal may decay over time (which may degrade or destroy the information stored in the memory cells). It may be necessary to periodically refresh the information in the memory cells by, for example, rewriting the information to restore the physical signal to an initial value.

As memory components have decreased in size, the density of memory cells has greatly increased. Repeated access to a particular memory cell or group of memory cells (often referred to as a ‘row hammer’) may cause an increased rate of data degradation in nearby memory cells. Memory devices use various schemes to identify addresses which are repeatedly accessed so that the nearby memory cells may be refreshed. It may be useful to increase the accuracy of the identification of memory cells that may need to be refreshed.

### BRIEF DESCRIPTION OF THE DRAWINGS

FIG. 1 is a block diagram of a semiconductor device according to at least one embodiment of the disclosure.

FIG. 2 is a block diagram of a memory cell array according to an embodiment of the present disclosure.

FIG. 3 is a block diagram of an activation counter initialization (ACI) control circuit that initializes an access counter value according to some embodiments of the present disclosure.

FIG. 4 is a schematic diagram of a portion of a memory array according to some embodiments of the present disclosure.

FIG. 5 is a timing diagram of example behaviors of an activation counter initialization (ACI) circuit according to some embodiments of the present disclosure.

FIG. 6 is a flow chart of a method according to some embodiments of the present disclosure.

FIG. 7 is a flow chart of a method according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory array includes a number of memory cells organized at the intersection of word lines (rows) and columns (bit lines). Information in the memory array may be accessed by one or more access operations, such as read or write operations. During an example access operation a word line may be activated based on a row address and then selected memory cells along that active word line may have their information read from or written to based on which bit lines are selected, which may be based on a column address. Information in the memory cells may decay over time. To prevent the loss of information, the memory array may be refreshed on a row by row basis (e.g., as part of an auto-refresh and/or self-refresh mode) to periodically refresh the memory cells. The speed at which the rows are refreshed (e.g., the maximum time any given row will go between refreshes) may be determined based on an expected rate of information decay.

Various patterns of access to a row (an aggressor row) may cause an increased rate of information decay in nearby memory cells (e.g., along victim rows). For example, a ‘row hammer’ may involve repeated accesses to the aggressor row which may increase a rate of decay in adjacent rows (and/or in rows which are further away). This increased rate of decay, above the rate expected by the refresh timing, may risk the loss of information in the victim rows. Accordingly, it may be important to track a number of accesses to each row to determine if they are aggressors, such that the victim rows can be identified and refreshed as part of a targeted refresh operation.

Some memories may count accesses to each row, which may be referred to as a per-row hammer tracking (PRHT) scheme or a per row activation counter (PRAC) scheme, where each word line has an associated access count value stored in counter memory cells along that word line. The access count value is used to determine how many times that word line has been accessed. When the word line is accessed the access count value may be changed (e.g., incremented) by a counter circuit and compared to a mitigation threshold by a comparator. If the access count value crosses the mitigation threshold, then the address may be added to an aggressor queue and during targeted refresh operations, the addresses in the queue are used to generate refresh addresses. After power up, the counter memory cells are populated with random-like bits. If the memory is immediately used, the random state of the bits may create various issues, such as an illusion of an aggressors, because some access count values start at a much higher value based on the random bits assigned at power up. There may be other situations which require re-initialization of the access counters, for example if refresh requirements are violated, placing the counters in an unknown state. There may be a need to initialize the access count values before memory operations begin (and/or when the counters are in an unknown state) to prevent the random state of the access count values from causing undesired memory operations.

The present disclosure is drawn to apparatuses, systems, and methods for activation counter initialization (ACI). A memory may be placed in an ACI mode. During the ACI mode, an ACI control circuit initializes, e.g., writes a value to or clears a value from, the access count values of the memory array to an initialization value. For example, the ACI mode may work through the array on a row-by-row basis initializing the access count values along each of the rows. By controlling the initial state of the access count values, it is less likely to have a false aggressor alert because none of the access count values start at a randomly high number, simulating an aggressor even after a small number of accesses. In some embodiments, the ACI mode may be a mandatory operation which must be performed after a power up (or other reset) before the memory is available for access operations.

In an example implementation, the memory may be placed in an ACI mode, for example based on a setting in a mode register, and during the ACI mode the memory may perform ACI operations. As part of an ACI operation, the memory may receive an ACI command and responsive to that an ACI control circuit may provide internal signals indicating that ACI operations should be performed. In some embodiments, the ACI command may be an existing type of command, such as a refresh command, which is used as an ACI command only when the device is in the ACI mode. An address counter circuit generates an ACI address based on the internal signal. A row decoder activates the word line(s) associated with the ACI address, and a counter control circuit writes an initialization value to the counter memory cells of the active word line responsive to an internal ACI signal.

In some embodiments, to increase the speed of ACI operations, multiple access count values may be initialized together. For example, after activating a first word line as part of an ACI operation, a second word line may be activated before the first word line is pre-charged. In this manner, a same initialization value along the bit lines coupled to the counter memory cells may be rapidly written to the counter memory cells of multiple word lines which, in turn, may decrease the time it takes to initialize the array.

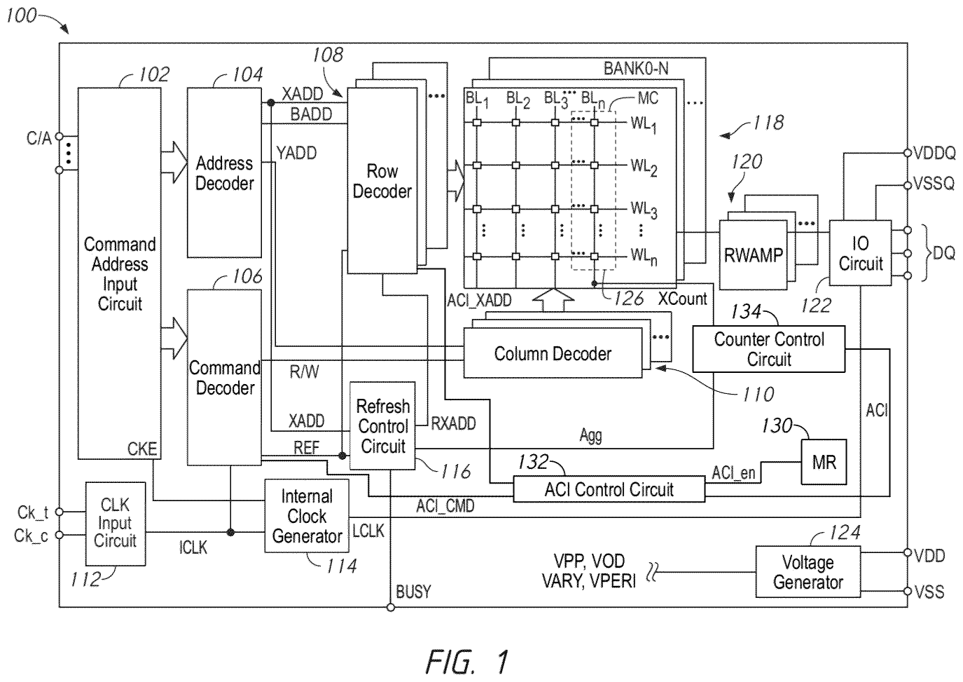

FIG. 1 is a block diagram of a semiconductor device according to at least one embodiment of the disclosure. The semiconductor device 100 may be a semiconductor memory device such as a DRAM device integrated on a single semiconductor chip.

The semiconductor device 100 includes a memory array 118. In the embodiment of FIG. 1, the memory array 118 is shown as including a number of memory banks, BANK0 to BANKN. For example, the memory may include 4 banks, 8 banks, or 16 banks. More or fewer banks may be included in the memory array 118 of other embodiments. Each memory bank includes a plurality of word lines WL (rows), a plurality of bit lines BL (columns), and a plurality of memory cells MC arranged at intersections of the plurality of word lines WL and the plurality of bit lines BL.

The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier (SAMP) (not shown in FIG. 1). Read data from the bit line BL is amplified by the sense amplifier SAMP, and transferred to read/write amplifiers 120 over complementary local data lines (LIOT/B), transfer gate (TG), and complementary main data lines (MIOT/B). Conversely, write data outputted from the read/write amplifiers 120 is transferred to the sense amplifier SAMP over the complementary main data lines MIOT/B, the transfer gate TG, and the complementary local data lines LIOT/B, and written in the memory cell MC coupled to the bit line BL.

Some of the memory cells may be set aside as counter memory cells 126. The counter memory cells may store access count values XCount, each of which is associated with one of the word lines. Each access count value XCount may be stored in counter memory cells 126 along the word line with which the access count value XCount is associated. The access count value XCount may be stored as a binary number, with each bit stored in a memory cell along the word line. For the sake of clarity, a single bit line of counter memory cells 126 is shown in FIG. 1. The number of counter memory cells 126 along each word line may be based on a number of bits of the access count value XCount. In some embodiments, extra counter memory cells 126 (e.g., more than the length of the number XCount) may be used, for example to store error correction information for the access count value XCount.

The counter memory cells 126 may be referred to as such due to their use (storing the access count values) and in some embodiments may be structurally similar to, or identical to, the other memory cells of the array. In some embodiments, the counter memory cells 126 may be grouped together (e.g., at the end of the word line). The counter memory cells 126 may be coupled along the same bit lines, which may be referred to as counter bit lines. Other distributions of the counter memory cells 126 along the word line may be used in other example embodiments. In some embodiments, the counter memory cells 126 may not be directly accessible by external devices such as controllers (e.g., to prevent the access count values from being overwritten). In other words, the counter bit lines may not be directly accessed by a normal column address.

The semiconductor device 100 may employ a plurality of external terminals that include command and address (C/A) terminals coupled to a command and address bus to receive commands and addresses, and a CS signal, clock terminals to receive clocks CK and /CK, data terminals DQ to provide data, and power supply terminals to receive power supply potentials VDD, VSS, VDDQ, and VSSQ.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 110 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line. When an access command is received, the command decoder 106 provides a row activation signal ACT, which activates the word line specified by the row address. At the end of an access operation, the command decoder 106 provides a pre-charge signal Pre, which pre-charges or deactivates the word line. When a row is activated, its access count value XCount is read out along the counter bit lines to a counter control circuit 134, which updates the access count value XCount.

The semiconductor device 100 may receive an access command which is a read command. When a read command is received, a bank address BADD and a column address YADD are timely supplied with the read command, read data is read from memory cells in the memory array 118 corresponding to the row address XADD and column address YADD. The read command is received by the command decoder 106, which provides internal commands so that read data from the memory array 118 is provided to the read/write amplifiers 120. The row decoder 108 activates the word line indicated by XADD, and the information in the memory cells along that word line is read out to their respective bit lines. When the word line is activated, the access count value XCount is read out to the counter control circuit 134, which updates the access count value XCount and writes it back to the counter memory cells along the active word line. The column decoder 110 provides a column select signal based on YADD which couples selected bit lines to the read/write amplifiers 120. A time after providing the activation signal, the row decoder 108 provides a pre-charge signal to deactivate the word line. The read data is output to outside from the data terminals DQ via the input/output circuit 122.

The semiconductor device 100 may receive an access command which is a write command. When the write command is received, a bank address BADD and a column address YADD are timely supplied with the write command, write data supplied to the data terminals DQ is written to memory cells in the memory array 118 corresponding to the row address and column address. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC. The row decoder 108 provides the activation signal to the word line indicated by XADD, which causes the values in the memory cells along the active word line to be read out to their respective bit lines. The access count value XCount along the activated word line is read out to the counter control circuit 134 which updates the access count value XCount and writes it back. The column decoder 110 provides a column select signal based on YADD and couples selected bit lines to the read/write amplifiers 120, which write the write data onto the selected bit lines. A time after activating the row, the row decoder 108 provides a pre-charge signal and deactivates the word line.

The semiconductor device 100 may also receive commands causing it to carry out refresh operations. For example, a controller of the memory may put the semiconductor device 100 into an auto-refresh mode and provide a refresh command. Responsive to the refresh command, the command decoder 106 provides a refresh signal REF. The semiconductor device 100 may also enter a self-refresh mode where the refresh signal REF is generated internally. Responsive to the refresh signal REF, one or more refresh operations are performed.

Responsive to the refresh signal REF, the refresh control circuit 116 performs one or more refresh operations by providing a refresh address RXADD, along with refresh signals (not shown in FIG. 1) to the row decoder 108. The row decoder 108 refreshes the word line(s) associated with the refresh address RXADD, for example by restoring a charge in the memory cells along the word line(s) to an initial value associated with the value of the bit stored in that memory cell.

When the refresh control circuit 116 performs refresh operations responsive to REF, it determines if the refresh operations are normal (or sequential) refresh operations or targeted refresh operations, or combinations thereof. In a normal refresh operation, the refresh address RXADD is generated based on a sequence of addresses. In other words the refresh address RXADD may be generated based on a previous value of the refresh address (e.g., RXADD(i)=RXADD(i−1)+1). The sequence logic used to generate the normal refresh addresses may cycle through each of the word lines of the memory array 118. For example, the refresh control circuit 116 may include an address counter and an address mapping circuit. The address counter may count through a sequence of values, and the address mapping circuit may generate the refresh address RXADD based on the position of the count in the sequence.

In a targeted refresh operation, the refresh address RXADD is generated based on an identified aggressor address stored in a targeted refresh queue of the refresh control circuit 116. The refresh address RXADD may represent victim addresses, which may be associated with word lines that have a spatial relationship with the word line associated with the identified aggressor address. For example, the refresh address RXADD may be word lines adjacent to the aggressor word line (e.g., RXADD=Aggressor+/−1). Other relationships (e.g., +/−2, +/−3, +/−4, etc.) may also be used.

In some embodiments, the normal refresh address may be associated with a different number of word lines than the targeted refresh address. The normal refresh address may be associated with more word lines than the targeted refresh address. For example, the normal refresh address may be truncated (compared to a row address XADD) and be associated with all the word lines whose addresses share the value of that truncated portion in common, while the targeted refresh address may be associated with a single word line.

The counter control circuit 134 may act as an aggressor detection circuit, which tells the refresh control circuit 116 if the current row address XADD is associated with an aggressor word line or not. For example, if the updated access count value XCount from the currently active word line crosses a mitigation threshold, then the counter control circuit 134 may provide an aggressor detected signal Agg to the refresh control circuit 116. Responsive to the aggressor detected signal Agg, the refresh control circuit 116 adds the current row address XADD to the targeted refresh queue. In some embodiments, the counter control circuit 134 may include a comparator which compares the updated access count value XCount to the mitigation threshold. In some embodiments, the counter control circuit 134 may inherently act as a comparator. For example, the threshold may represent the maximum value of the access count value XCount, and when the access count value XCount reaches a maximum value and ‘rolls over’ back to an initial value, the counter control circuit 134 provides an aggressor detected signal Agg.

During an activation counter initialization (ACI) mode, the device 100 may perform ACI operations in order to initialize the access counts XCount of the memory array 118. In some embodiments, a controller of the memory may put the semiconductor device 100 into an ACI mode and, if applicable, provide the ACI command. In some embodiments, the semiconductor device 100 may enter an ACI mode automatically (e.g., after power up). In some embodiments, the ACI operations may be performed automatically once the device is in the ACI mode. In some embodiments, the semiconductor device 100 may receive ACI commands causing it to carry out ACI operations. In some embodiments, a command which is normally used for some other purpose may be used as the ACI command while the device is in the ACI mode. For example, while in the ACI mode, the device 100 may respond to refresh commands by performing ACI operations rather than by performing refresh operations. In order to perform ACI operations (e.g., based on an ACI command or based on internal timing), the command decoder 106 provides an ACI command signal ACI_CMD.

Responsive to the ACI command signal ACI_CMD, the ACI control circuit 132 performs one or more ACI operations by providing an ACI address ACI_XADD, along with other ACI signals (not shown in FIG. 1) to the row decoder 108 and by providing ACI signals ACI to the counter control circuit 134. The row decoder 108 activates the word line(s) associated with the ACI address ACI_XADD. Responsive to the ACI signal ACI, when a word line is activated, the counter control circuit 134 initializes the counter memory cells along the active word line(s) by writing an initialization value to the counter memory cells associated with the activated word line(s). In some embodiments, the initialization value may be a predetermined value, such as 0. The initialization value written to the access count value XCount may be the same or different for every word line. The ACI operations may be repeated until all the access count values XCount of the memory array 118 are initialized.

The semiconductor device 100 includes one or more registers where information and/or settings of the semiconductor device 100 are stored. For example, FIG. 1 shows a mode register 130, which includes a number of registers which may be used to store settings, properties, measured quantities, etc. related to the operation of the semiconductor device 100. The mode register may be organized into registers, which may be organized into sub-units such as operation codes (or op-codes). A controller of the semiconductor device 100 may access specified registers (or op-codes) by performing mode register read or write operations. Some registers (or op-codes) may be read-only. The memory device 100 may also retrieve information from the mode register and change information in the mode register 130.

As discussed above, the semiconductor device 100 may be placed in an ACI mode. For example, an ACI register of the mode register 130 may have a value which indicates if the device is in the ACI mode or not. If the register is set to an inactive state, then the device is not in an ACI mode (e.g., is in a normal operational mode). If the register is set to an active state, then the device is in an ACI mode. When the device is in an ACI mode, access operations to the memory device may be restricted or prevented. For example, while the ACI register is active, the controller may be prevented from accessing the memory array 118.

As well as enabling the ACI mode, the mode register may include various other registers (or portions thereof) useful for managing the ACI mode and ACI operations. For example, the mode register 130 may include an ACI status indicator. The ACI control circuit 132 may update the status indicator in the mode register 130 to indicate when ACI operations are complete (e.g., all access count values have been initialized) during an ACI mode. A controller may monitor the status indicator and deactivate the ACI mode when the status indicator changes to indicate that ACI operations are complete. In some embodiments, the register which enables the ACI mode may be dependent on one or more other settings. For example, if PRAC is not enabled on the device by a PRAC register, then it may not be possible to enable an ACI mode (as the counter values are not used, and thus initialization would serve no purpose).

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The internal potential VPP is mainly used in the row decoder 108, the internal potentials VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

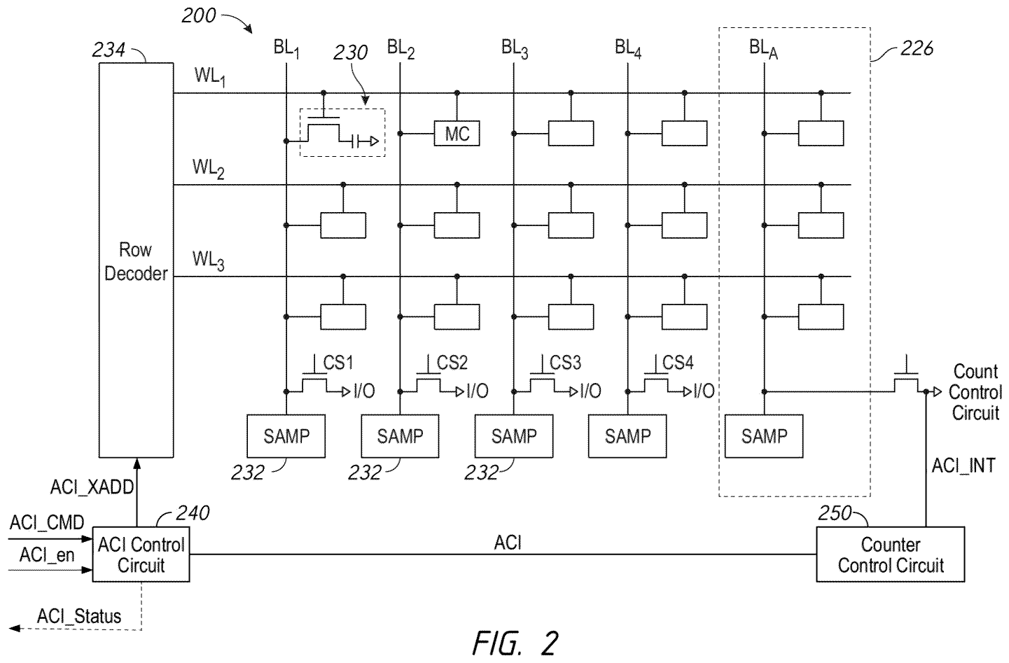

FIG. 2 is a block diagram of a memory cell array according to an embodiment of the present disclosure. The memory cell array 200 may represent an exemplary portion of a memory array, such as the memory array 118 of FIG. 1. The memory cell array 200 includes a plurality of word lines WL (rows) and bit lines BL (columns). A row decoder 234 (e.g., row decoder 108 of FIG. 1) is coupled to the rows. A plurality of memory cells MC, such as example memory cell 230, are located at the intersection of the rows and columns. Some of the memory cells may be set aside as counter memory cells 226. The memory array 200 includes a number of sense amplifiers 232.

Each of the memory cells MC may store information. In some embodiments, the information may be stored as a binary code, and each memory cell MC may store a bit, which may be either at a logical high or a logical low level. Example memory cell 230 shows a particular implementation which may be used to store a bit of information in some embodiments. Other types of memory cells may be used in other examples. In the example memory cell 230, a capacitive element stores the bit of information as a charge. A first charge level may represent a logical high level, while a second charge level may represent a logical low level. One node of the capacitive element is coupled to a reference voltage (e.g., VSS). The other node of the capacitive element is coupled to a switch. In the example memory cell 230, the switch is implemented using a transistor. A sense node of the switch (e.g., the gate of the transistor) is coupled to the word line. The word line WL may be accessed by the row driver 234 setting a voltage along the word line such that the switches in the memory cells MC are closed, coupling the capacitive elements (or other bit storage element) to the associated bit lines BL.

The sense amplifiers 232 may read or write a value of a bit of information along the bit line BL to memory cell MC (or memory cells) at the accessed word line WL. The sense amplifiers 232 may convert a signal along the bit line BL to a signal which is ‘readable’ by other elements of the memory device (e.g., by amplifying a voltage). The bit lines BL may be coupled to an input/output circuit (e.g., input/output circuit 122 of FIG. 1) via a respective column select switch, which may be a column select transistor activated by a column select signal CS. In the example view of FIG. 2, five bit lines BL₁-BL_{A} are shown, four “normal” bits lines BL₁-BL₄, each accessed by a respective column select signal CS1 to CS4, and one bit line BL_{A} associated with the counter memory cells 226. Accordingly, each word line WL of FIG. 2 stores five total bits, one of which is designated for an access count value. It should be understood that FIG. 2 is a simplified view, and that many more (or fewer) memory cells, and/or a different ratio of normal memory cells to counter memory cells 226 may be used.

In an example read operation, when a word line WL is accessed, the memory cells MC may provide their charge onto the coupled bit lines BL which may cause a change in a voltage and/or current along the bit line BL. The sense amplifier 232 may determine a logical level of the accessed memory cell MC based on the resulting voltage and/or current along the bit line BL, and may provide a signal corresponding to the logical level through the column select transistor to the input/output circuit.

In an example write operation, the sense amplifiers 232 may receive a signal indicating a logical level to be written to the accessed memory cells from the input/output circuit. The sense amplifier 232 may provide a voltage and/or current along the coupled bit line BL (e.g., along the bit lines BL with active column select transistors) at a level corresponding to the logical level to be written. The voltage and/or current along the bit line BL may charge the capacitive element at the intersection of the bit line BL with an accessed word line WL to a charge level associated with the written logical level. In this manner, by specifying the row which is accessed, and which bit lines BL to record data from (and/or write data to), specific memory cells MC may be accessed during one or more operations of the memory device.

During an example refresh operation (either targeted or auto-refresh), the word line WL to be refreshed may be read, and then a logical value read from each of the memory cells along that word line WL may be written back to the same memory cells. In this manner the level of charge in the refreshed memory cells MC may be restored to the full value associated with the logical level stored in that memory cell.

During an example ACI operation, an ACI control circuit 240 (e.g., ACI control circuit 132 of FIG. 1) receives an ACI command signal ACI_CMD. In some embodiments the ACI_CMD may be received along with an ACI enable signal ACI_en. The ACI enable signal ACI_en indicates if the memory device is in an ACI mode or not. For example, the ACI enable signal ACI_en may be provided by a mode register such as 130 of FIG. 1. The ACI command signal ACI_CMD may be provided by a command decoder such as 106 of FIG. 1. In some embodiments, the ACI command signal ACI_CMD may be a command used for another purpose outside the ACI mode, such as a refresh command, which is interpreted as an ACI command when the device is in the ACI mode (e.g., when ACI_en is active).

Responsive to the ACI command signal ACI_CMD (when the enable signal ACI_en is active), the ACI control circuit 240 performs an ACI operation by providing an ACI address ACI_XADD, along with ACI signals (not shown in FIG. 2), to the row decoder 234. The row decoder 234 activates the word line(s) WL associated with the ACI address ACI_XADD. Also, responsive to the ACI command signal ACI_CMD when the enable signal ACI_en is active, the ACI control circuit 240 performs an ACI operation by providing an ACI signal ACI to the counter control circuit 250 (e.g., counter control circuit 134 of FIG. 1). Responsive to the ACI signal ACI, the counter control circuit 250 provides an ACI initialization value ACI_INT to the sense amplifier 232 coupled to the counter memory cells 226 that is driven on to the counter memory cells 226 of the active word lines WL. In some embodiments, an address counter coupled with the ACI control circuit 240 provides the ACI address to the row decoder 234. In some embodiments, the address counter is a component that is shared with an existing system, such as the refresh control circuit. For example the address counter may be an address counter which is used to generate refresh addresses when the device is not in the ACI mode.

In some embodiments, responsive to the ACI address ACI_XADD and ACI signals (not shown in FIG. 2), the row driver 234 may begin to activate the word lines WL of a memory array 200 one-by-one. After an amount of time, beginning when the word line WL is activated, the row decoder 234 may deactivate each word line WL, for example with a pre-charge signal. An activation time delay may be implemented to determine when a subsequent word line WL is activated. During normal operations (e.g., when the device is not in the ACI mode) the time delay may be used to prevent two word lines which are coupled to the same sense amplifiers from being active at the same time (e.g., the delay may be set to ensure that the first word line pre-charges before the next word line activates). In some embodiments, during the ACI mode, the activation time delay may be shortened such that a subsequent word line WL is activated before the currently active word line WL deactivates, i.e., pre-charges. In this manner, two word lines in a same section may both be active at the same time during an ACI mode.

In some embodiments, the ACI control circuit 240 may provide a signal to indicate that the ACI operations have completed. The ACI control circuit 240 may provide a signal ACI_status which indicates if the ACI operations are complete. For example, the ACI control circuit 240 may monitor a number of ACI_CMDs and when a specified number of ACI_CMDs are received, the ACI control circuit 240 provides the signal ACI_status. In another example, the address counter may be used and when the address counter recycles to an initial value (e.g., indicating that all word lines have been refreshed) the ACI control circuit 240 provides ACI_status. The value of ACI_status may be written to a register (e.g., in mode register 130 of FIG. 1) and used as an indicator that the ACI operations are done. Responsive to ACI_status being active, the controller may end the ACI mode, for example by resetting ACI_en.

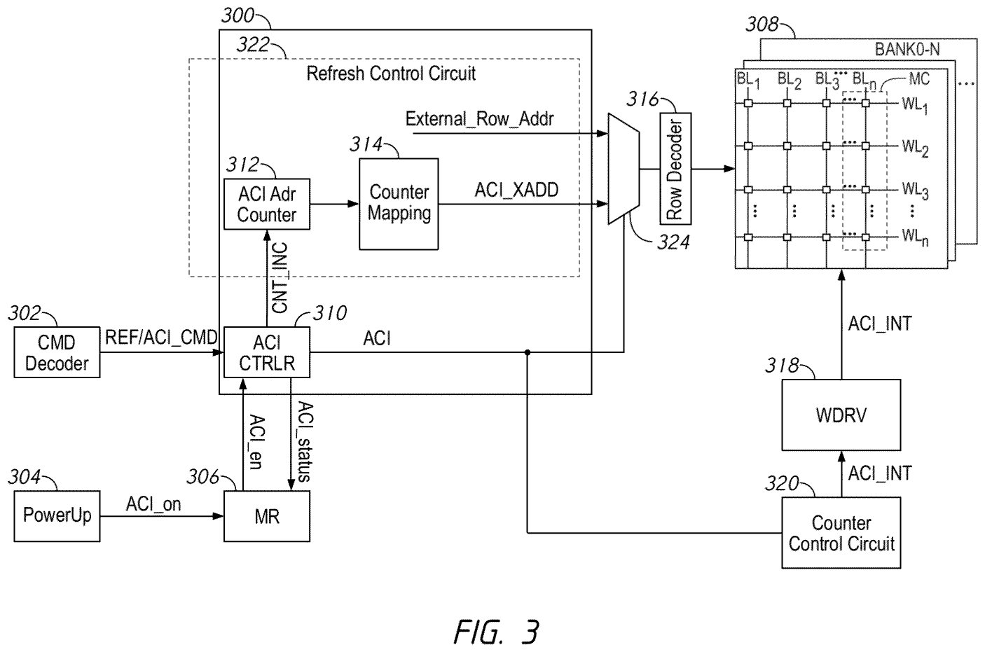

FIG. 3 is a block diagram of an activation counter initialization (ACI) control circuit that initializes an access counter value according to some embodiments of the present disclosure. The ACI control circuit 300 may, in some embodiments, implement the ACI control circuit 132 of FIG. 1 and/or 240 of FIG. 2. The dotted line around the refresh control circuit 322 is shown to represent that, in certain embodiments, each of the components within the dotted line may be unique to the ACI control circuit 300 or may be shared with another circuit of the memory device, such as a refresh control circuit (e.g., 116 of FIG. 1). For example, the ACI address counter 312 may be an existing address counter component belonging to the refresh control circuit.

During an example ACI operation, an ACI controller 310 receives an ACI command signal ACI_CMD from a command decoder 302 (e.g., command decoder 106 of FIG. 1) and receives an ACI enable signal ACI_en from a mode register 306 (e.g., mode register 130 of FIG. 1). The ACI enable signal ACI_en indicates if the memory device is in an ACI mode or not. In some embodiments, the memory device is automatically placed in an ACI mode after power up and an internal ACI mode signal ACI_on is provided to the mode register 306. In some embodiments, a controller may perform a mode register write operation to set the value ACI_en to an active state. When the device is in the ACI mode, access operations to the memory device may be restricted or prevented. For example, while the value ACI_en in the mode register 306 is active, the controller may be prevented from accessing the memory array 308. Similarly, other operations may also be modified by the ACI mode being active. For example, while ACI_en is active, normal refresh operations may not be performed, because the ACI mode must occur before normal memory operations, and thus there is no data to protect in the array 308.

Responsive to the ACI command signal ACI_CMD when the ACI enable signal ACI_en is active, the ACI controller 310 performs an ACI operation by providing a count increment signal CNT_INC to the ACI address counter 312. The ACI address counter 312 provides a signal to the counter mapping circuit 314 which provides an ACI address ACI_XADD to the row driver 316 (e.g., row decoder 108 of FIG. 1 and/or row driver 234 of FIG. 2). The ACI address ACI_XADD may correspond to a single word line address or multiple word line addresses. For example, the ACI address may be truncated compared to a full row address XADD, and the ACI address may be associated with every word line which is addressed by the truncated portion. The row decoder 316 activates a word line or word lines according to the ACI address ACI_XADD. In some embodiments, the ACI address counter 312 and the counter mapping circuit 314 may be existing components of a refresh control circuit such as 116 of FIG. 1.

While the ACI enable signal ACI_en is active, the ACI controller 310 also provides an ACI signal ACI to the counter control circuit 320 (e.g., counter control circuit 134 of FIG. 1 and/or counter control circuit 250 of FIG. 2). When the ACI signal ACI is received, the counter control circuit 320 may operate differently than during a “normal” mode. For example, when the device is in the ACI mode, the counter control circuit 320 may only perform write operations to initialize the counter memory cells but in the “normal” mode, the counter control circuit 320 may perform read-modify-write operations to read the count value, modify it (e.g., by incrementing), and then write the modified value back. Responsive to the ACI signal ACI, the counter control circuit 320 provides an ACI initialization value ACI_INT to the write driver 318 coupled to the counter memory cells of the memory array 308 (e.g., memory array 118 of FIG. 1). When a word line is activated by the row decoder 316 (e.g., responsive to ACI_XADD), the write driver 318 then writes the initialization value ACI_INT to the counter memory cells of the activated word lines of the memory array 308. For example, the write driver 318 may fire the sense amplifiers (e.g., 232 of FIG. 2) of the memory array 308 and drive the initialization value ACI_INT onto the counter bit lines. When a word line is activated by the row driver 316 responsive to ACI_XADD, the value along the counter bit lines is written to the counter memory cells along the active word line.

After performing an initial ACI operation on an address, the ACI controller 310 may provide a count increment signal CNT_INC to the ACI address counter 312. The ACI address counter 312 provides a signal to a counter mapping circuit 314 which in turn provides a next ACI address ACI_XADD to the row decoder 316. The row decoder then activates the next word line or word lines of the memory array 308, such as by incrementing the address. In some embodiments, the next word line may activate before the previous word line deactivates, i.e., pre-charges.

The ACI controller 310 may also provide an ACI status signal ACI_status to the mode register 306 to indicate the completion of the ACI operation. For example, the address counter 312 and/or counter mapping circuit 314 may provide a signal (not shown) which indicates that all count values have been initialized (e.g., each unique value of ACI_XADD has been generated) and/or the ACI controller 310 may count a number of times that ACI_CMD is received. In some embodiments, responsive to the ACI status signal ACI_status, the mode register may set the ACI enable register value ACI_en to an inactive state so the device is not in an ACI mode (e.g., is in a normal operational mode). In some embodiments, a controller may monitor ACI_status during the ACI mode (e.g., by performing mode register read operations on ACI_status). Once ACI_status changes, the controller may perform a mode register write operation to change a status of ACI_en to inactive and end the ACI mode.

The mode register 306 may include various settings which are used to enable the ACI mode and control the operation thereof. In an example implementation, the ACI enable and status registers may be op-codes within a register set aside for PRAC. For example the register MR70 may include information related to PRAC such as a first op-code OP[1] which enables or disables the use of access counts (e.g., which enables or disables the PRAC feature), a second op-code OP[2] which acts as ACI_en, and a third op-code OP[3] which acts as ACI_status. In some embodiments, the op-codes may be single-bit values which are set to either inactive (0 or 0_{B}) or active (1 or 1_{B}). Other mode registers and/or op-codes may be used in other example implementations. A controller, or host, of the memory may interact with the mode register 306 to enable and disable the ACI mode.

Upon power-up or any time that DRAM refresh requirements are violated, the Activation Counter bits may be in an unknown state, requiring an initialization to put the bits into a known state. The default state for DDR5 Per Row Activation Counting (PRAC) is disabled (MR70 OP[1]=0_{B}), as this is an optional feature. Prior to initialization of the activation counter bits, PRAC shall be enabled (MR70: OP[1]=1_{B}) by the host. Once PRAC is enabled, a full array Activation Counter Initialization (ACI) shall be performed. The DRAM will not track activation counts, nor issue an Alert Back-Off (ABO), until the Activation Counter bits are initialized. Legacy mode for maintaining of data integrity will not be performed after PRAC is enabled.

To initialize the Activation Counter bits, the host sets MR70: OP[2]=1_{B} to indicate to the DRAM that a full array refresh will take place. Only refresh commands are permitted during initialization. The refresh commands during the initialization period may be issued by the host up to two times (2×) the normal refresh rate (Normal mode: 0.5*tREF11; FGR mode: 0.5*tREF12). Upon completion of a full refresh cycle, the DRAM shall indicate completion by setting MR70: OP[3]=1_{B}, which the host shall then follow by setting MR70: OP[2]=0_{B}. The DRAM shall start counting activations from that point forward and issue the ABO as necessary.

During the ACI mode, the DRAM does not need to refresh the main array, and any data previously written may be corrupted. If the host reenters Activation Counter Initialization by setting M R70: OP[2]=1_{B}, the DRAM will reset MR70: OP[3]=0_{B} until the initialization has been completed. Likewise, a system reset to disable PRAG (MR70: OP[1]=0_{B}) will also reset MR70 OP[3]=0_{B}.

Like normal DRAM cells, the Activation Counter bits require refresh to maintain the stored values. Any time refresh is violated during the ACI operation or after the ACI operation in modes like MPSM or other idle periods, the ACI operation shall be performed by the host to set the Activation Counter bits to a known state. Since array data is also corrupted by refresh violations, previous Activation Counter values become irrelevant.

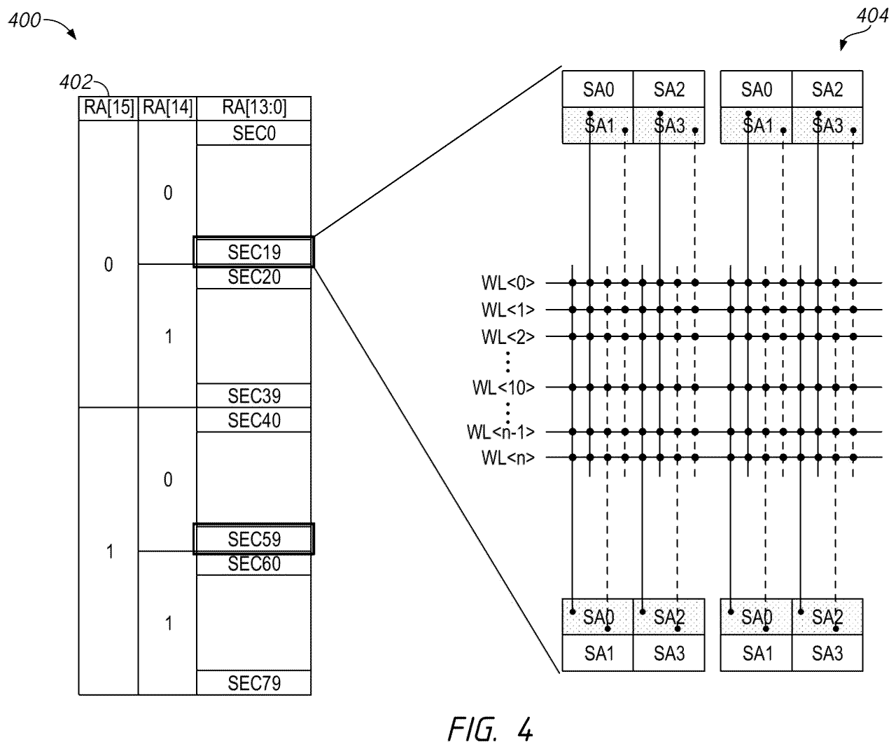

FIG. 4 is a schematic diagram of a portion of a memory array according to some embodiments of the present disclosure. FIG. 4 shows portions of a memory array 400 such as the memory array 118 of FIG. 1, 200 of FIG. 2, and/or 308 of FIG. 3. In some embodiments, a word line address may comprise sixteen bits. During an example ACI operation, the ACI address, e.g., ACI_XADD, provided to the row decoder, e.g., 316 of FIG. 3, may truncate one or more bits in order to activate more word lines simultaneously for initialization. For example, a bit of the row address, depicted as RA[15] in a portion of the row address bits 402, may be truncated. A target section corresponding to an address associated with a portion of the word line address bits 402 may be activated, for example SEC19, for initialization. The target section may be associated with a plurality of word lines 404, e.g., WL<0> through WL<n>. In some embodiments, each word line WL<0> through WL<n> shown in FIG. 4 may represent multiple word lines. For example, FIG. 4 may represent an operation in a single section, however the operation shown in FIG. 4 may be performed in multiple sections simultaneously.

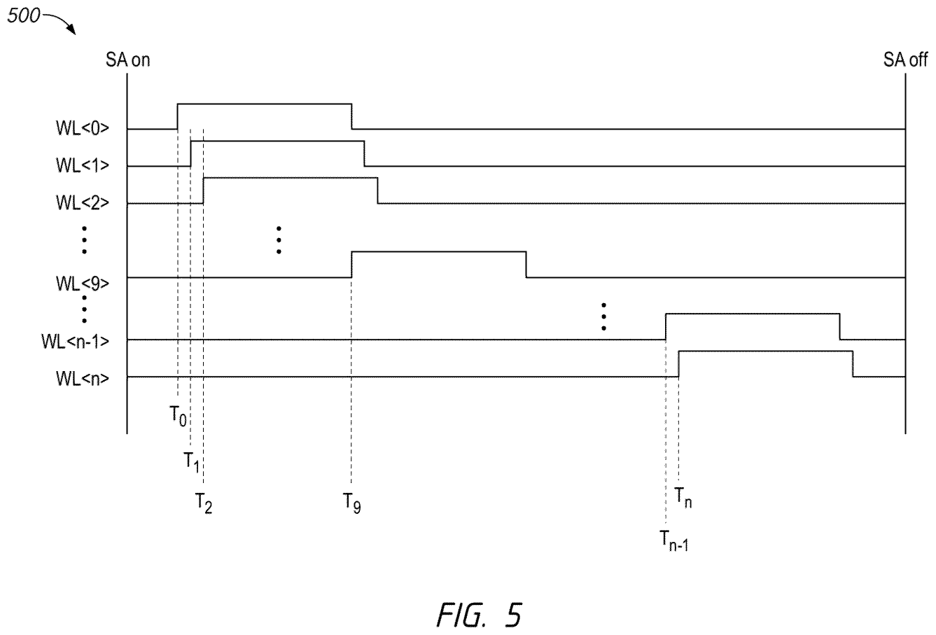

Each word line may be coupled to a sense amplifier SA, e.g., 232 of FIG. 2, which drives an ACI initialization value, e.g., ACI_INT of FIG. 3, on to the activated word lines WL. In some embodiments, multiple target sections, for example two, may be activated in parallel, e.g., SEC19 and SEC59. The counter control circuit (e.g., 320 of FIG. 3) may drive the initialization value ACI_INT onto word lines in both sections simultaneously. In some embodiments, multiple word lines within an active section may also be active simultaneously. An example of multiple active word lines is described in more detail in FIG. 5. In some embodiments, multiple sections may be active at a same time. For example, the word line WL<0> may be activated in multiple sections simultaneously. By activating multiple sections at the same time, having multiple word lines in a section active at a same time, or combinations thereof, the number of access counts initialized at one time may be increased.

FIG. 5 is a timing diagram of example behaviors of an activation counter initialization (ACI) circuit according to some embodiments of the present disclosure. The timing diagram 500 of FIG. 5 may, in some embodiments, represent the operations of a row decoder such as 108 of FIG. 1, 234 of FIG. 2, and/or 316 of FIG. 3 during an ACI mode. The timing diagram 500 may represent operations in a single section, e.g., SEC19 of FIG. 4, of a memory array such as the memory array 118 of FIG. 1, 200 of FIG. 2, 308 of FIG. 3, and/or 400 of FIG. 4. In some embodiments, multiple sections, e.g., SEC19 and SEC59 of FIG. 4, may be active at the same time and each section may operate in a manner similar to what is shown in FIG. 5.

During an example ACI operation, responsive to an ACI address ACI_XADD, a row decoder, such as 108 of FIG. 1, 234 of FIG. 2, and/or 316 of FIG. 3, activates the word lines associated with the ACI address ACI_XADD, e.g., one-by-one beginning at time T₀. For example, a first ACI address ACI_XADD may activate WL<0> then a second value of the ACI address may activate WL<1> and so forth. In some embodiments, word line WL may represent multiple word lines. In some embodiments, the ACI address ACI_XADD may activate WL<0> in multiple sections at the same time (e.g., because ACI_XADD is truncated compared to a full row address).

After the first word line, WL<0>, activates but before it deactivates, e.g., pre-charges, the row decoder activates a second word line WL<1> at time T₁. Similarly, a third word line WL<2> is activated at a time T₂, and so forth up to a ninth word line WL<9> which activates at a time T9. In some embodiments, multiple word lines WL of a section may be activated simultaneously. For example, the time between To when WL<0> is activated and T₁ when WL<1> is activated is zero. In the example embodiment shown in FIG. 5, ten word lines WL<0> to WL<9> are active at the same time. Shortly after the time T9, when word line WL<9> activates, the first word line WL<0> pre-charges. Accordingly, when a next word line (WL<10>, not shown) activates, ten word lines will still be active, WL<1> to WL<10>.

In this manner, multiple word lines WL of a section, for example up to ten word lines, may be activated at the same time. In an example implementation, the activation delay, i.e., the time between T₀ and T₁, may be 5 ns. Thus, the ACI operation, i.e., the time from when the sense amplifiers turn on SAₒₙ to when they turn off SA_{off}, completes in approximately 180 μs. In another embodiment, the activation delay may be 25 ns and the ACI operation, thus, completes in approximately 1 ms.

Other example embodiments may be set to include other numbers of word lines within a section which are activated at once. For example, another example embodiment may use two word lines within a section active at once. The number of word lines within a section which are active at once (e.g., the number of word lines which are activated at once) may influence the timing or number of ACI operations which occur before all word lines are initialized. For example, if two word lines are active within a section at once for each ACI command, then there may be half as many ACI commands before all word lines are refreshed compared to if only one word line is active. Similarly, in some embodiments, the timing at which the host or controller sends ACI commands may change based on how many word lines in a section are initialized at once. For example, if two word lines are initialized at once then ACI commands may be sent twice as fast as refresh commands.

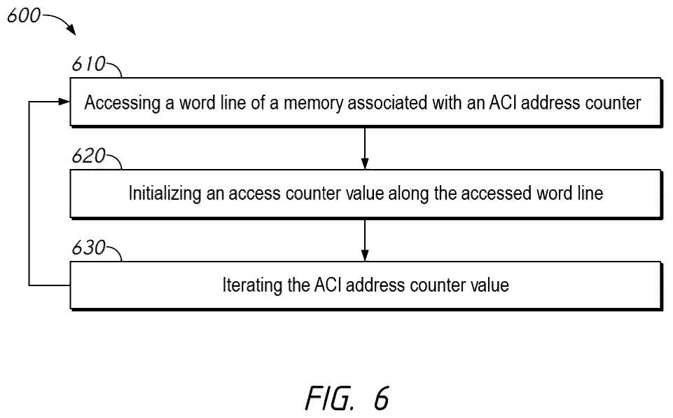

FIG. 6 is a flow chart of a method according to some embodiments of the present disclosure. The method 600 may, in some embodiments, be implemented by one or more of the apparatuses or systems described herein. For example, method 600 may be performed by the semiconductor device 100 of FIG. 1 and/or the ACI control circuits of FIGS. 2 and/or 3.

The method 600 may include box 610, which describes accessing a word line of a memory associated with an ACI address counter. For example, the method 600 may include receiving the ACI address and activating the one or more word lines associated with the address with the row decoder (e.g., 108 of FIG. 1, 234 of FIG. 2, and/or 316 of FIG. 3) responsive to the ACI address. The method 600 may include receiving an ACI command signal from a command decoder (e.g., 106 of FIG. 1 and/or 302 of FIG. 3) responsive to an external command. The method 600 may include entering an ACI mode automatically upon power up. The method 600 may include entering an ACI mode responsive to a mode register write operation (e.g., to set an ACI enable value in the mode register).

Box 610 is followed by box 620, which describes initializing an access counter value, such as a PRAC counter value, along the accessed word line. Initializing may involve writing an initialization value to the counter memory cells along the accessed word line, for example, by sending an ACI signal ACI to the counter control circuit (e.g., 320 of FIG. 3). The initialization value may be a single value written to all counter memory cells or it may be different values. The initialization value may be predetermined or randomly generated.

Box 620 is followed by box 630, which describes iterating the ACI address counter value. The ACI address counter may be iterated by incrementing the address bits associated with the word lines. For example, the ACI address counter may be iterated by sending a count increment signal CNT_INC to the ACI address counter (e.g., 312 of FIG. 3). The method 600 may include initializing the counter memory cells of every word line in a memory array (e.g. 118 of FIG. 1, 200 of FIG. 2, 308 of FIG. 3, and/or 400 of FIG. 4).

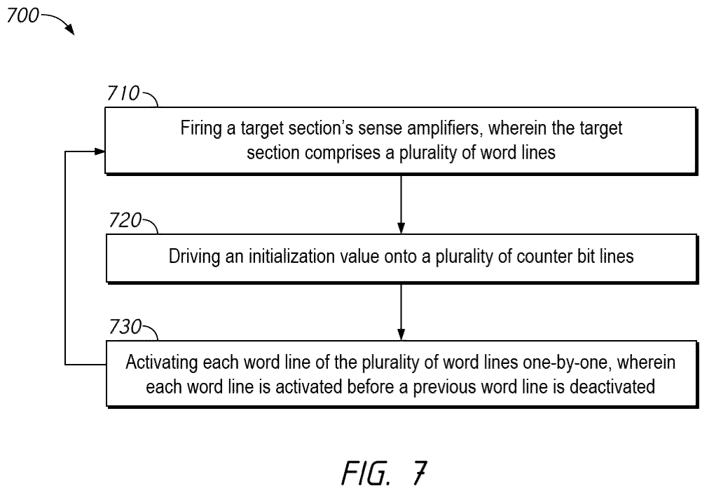

FIG. 7 is a flow chart of a method according to some embodiments of the present disclosure. The method 700 may, in some embodiments, be implemented by one or more of the apparatuses or systems described herein. For example, method 700 may be performed by the semiconductor device 100 of FIG. 1 and/or the ACI control circuits of FIGS. 2 and/or 3.

The method 700 may include box 710, which describes firing a target section's sense amplifiers. The sense amplifiers (e.g., 232 of FIG. 2) may be fired responsive to an ACI initialization value (e.g., ACI_INT of FIG. 2 and/or FIG. 3) during an ACI operation. For example, the method 700 may include providing an ACI command signal (e.g., ACI_CMD of FIGS. 1-3) to an ACI controller (e.g., 310 of FIG. 3) which provides the ACI signal (e.g., ACI of FIG. 3) to a counter control circuit (e.g., 134 of FIG. 1, 250 of FIG. 2, and/or 320 of FIG. 3). The counter control circuit may provide an ACI initialization value (e.g., ACI_INT of FIG. 3) to a write driver (e.g., 318 of FIG. 3) which fires the sense amplifiers.

Box 710 is followed by box 720, which describes driving an initialization value onto the counter bit lines. The method 700 may include providing an initialization value to the sense amplifiers (e.g., 232 of FIG. 2) from the counter control circuit (e.g., 134 of FIG. 1, 250 of FIG. 2, and/or 320 of FIG. 3) responsive to an ACI initialization value (e.g., ACI_INT of FIG. 2 and/or FIG. 3). In some embodiments, the initialization value may be predetermined. In some embodiments, the initialization value may be the same for every counter bit line.

Box 720 is followed by box 730, which describes activating each word line in the target section one-by-one, wherein each word line is activated before a previous word line is deactivated, or pre-charged. The method 700 may include deactivating each word line after an amount of time. The method 700 may include a delay between the activation of a word line and the next word line for initialization that is shorter than the total amount of time the first word line is on. For example, the method 700 may include an activation delay of 5 ns between the activation of each word line causing up to ten word lines to be activated at a time. The method 700 may be repeated until all word lines are initialized.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a plurality of word lines each coupled to a respective plurality of memory cells, wherein a portion of the plurality of memory cells are counter memory cells configured to store a plurality of access count values associated with a number of times a respective word line of the plurality of word lines has been accessed; and
an activation counter initialization (ACI) control circuit configured to initialize the plurality of access count values as part of an ACI operation.

2. The apparatus of claim 1, further comprising a counter control circuit configured to:
read the respective access count value when one word line of the plurality of word lines is activated, update the access count value, and write the access count value back to the counter memory cells of the word line as part of an access operation; or
write an initialization value to the counter memory cells as part of the ACI operation.

3. The apparatus of claim 1, wherein a next word line is activated before a first word line is deactivated as a part of the ACI operation.

4. The apparatus of claim 3, wherein the ACI control circuit is further configured to activate the next word line after a first time and deactivate the first word line after a second time, wherein the second time is longer than the first time.

5. The apparatus of claim 1, further comprising:
a mode register configured to store an ACI status, wherein the ACI control circuit is configured to set the ACI status to an active level after initializing each of the plurality of access count values.

6. The apparatus of claim 1, further comprising an address counter configured to generate an ACI row address responsive to the count increment signal as part of the ACI operation.

7. The apparatus of claim 1, further comprising a refresh control circuit configured to determine if the respective word line is an aggressor word line based, in part, on the access count value.

8. An apparatus comprising:
a memory array comprising a plurality of word lines each associated with one of a plurality of access count values;
an activation counter initialization (ACI) controller configured to provide a count increment signal and an ACI signal during an ACI operation;
an address counter configured to generate a row address responsive to the count increment signal;
a row decoder configured to activate one or more of the word lines based on the row address; and
a counter control circuit configured to access each of the word lines and initialize the plurality of access count values to an initialization value.

9. The apparatus of claim 8 further comprising:
a counter mapping circuit configured to map an ACI address to a plurality of row addresses to initialize multiple count values at a time.

10. The apparatus of claim 9, wherein the address counter and the counter mapping circuit are existing components of a refresh control circuit.

11. The apparatus of claim 9, wherein the address counter is configured to generate a refresh address when not in an ACI mode.

12. The apparatus of claim 8, further comprising:
a mode register configured to store an ACI status, wherein the ACI controller is configured to set the ACI status to an active level after initializing each of the plurality of access count values.

13. The apparatus of claim 8, wherein the initialization value is a predetermined value.

14. The apparatus of claim 8, wherein the ACI operation is triggered by an external command.

15. The apparatus of claim 14, wherein the external command is a refresh command.

16. A method comprising:
accessing a word line of a memory associated with ACI address counter;
initializing an access counter value along the accessed word line;
iterating the ACI address counter value.

17. The method of claim 16, further comprising:
firing a target section's sense amplifiers, wherein the target section comprises a plurality of word lines;
driving an initialization value onto a plurality of counter bit lines; and
activating each word line of the plurality of word lines one-by-one, wherein each word line is activated before a previous word line is deactivated.

18. The method of claim 16, further comprising enabling an ACI mode.

19. The method of claim 18, further comprising setting a mode register bit to indicate the ACI mode is enabled.

20. The method of claim 19, further comprising setting a second mode register bit to indicate the ACI mode is complete.

21. A method comprising:
enabling a first op-code of a register to enable per-row activation counting on a memory device;
setting a second op-code of a register to an active value to enable an access counter initialization (ACI) mode;
issuing refresh commands to perform ACI operations;
checking a third op-code of the register; and
setting the second op-code to an inactive value responsive to the third op-code being active.

22. The method of claim 21, further comprising issuing the refresh commands at twice a normal refresh rate.

23. The method of claim 21, further comprising not tracking activation counts with the memory device during the ACI mode.

24. The method of claim 21, further comprising only issuing refresh commands after setting the second op-code to the active value until setting the second op-code to the inactive value.

25. An apparatus comprising:
a memory array comprising a plurality of word lines;
a mode register including a register with a first, second, and third operational code (op-code); and
an access counter initialization (ACI) control circuit configured to enter an ACI mode responsive to the second op-code being set, configured to perform ACI operations on the plurality of word lines responsive to refresh commands in the ACI mode, and configured to set the third op-code responsive to completing ACI operations on the plurality of word lines.

26. The apparatus of claim 25, further comprising a refresh control circuit configured to not perform refresh operations while the apparatus is in the ACI mode.

27. The apparatus of claim 25, wherein the ACI control circuit is configured to set the third op-code responsive to performing a full refresh cycle.

28. The apparatus of claim 25, wherein the ACI control circuit is configured to reset the value of the third op-code responsive to the second op-code being set.

29. The apparatus of claim 28, wherein the ACI control circuit is configured to reset the value of the third op-code responsive to the first op-code being disabled.

30. The apparatus of claim 25, further comprising a refresh control circuit configured to enable per-row activation counting (PRAC) responsive to the first op-code being set.
